(19) United States
(12) Patent Application Publication
(10) Pub. No.: US 2025/0019836 A1
(43) Pub. Date: Jan. 16, 2025

(54) TREATMENT LIQUID, TREATMENT METHOD, AND METHOD FOR MANUFACTURING ELECTRONIC DEVICE

(71) Applicant: FUJIFILM Corporation, Tokyo (JP)

(72) Inventors: Kohei HAYASHI, Haibara-gun (JP); Moe NARITA, Haibara-gun (JP); Atsushi MIZUTANI, Haibara-gun (JP)

(73) Assignee: FUJIFILM Corporation, Tokyo (JP)

(21) Appl. No.: 18/889,891

(22) Filed: Sep. 19, 2024

Related U.S. Application Data
(63) Continuation of application No. PCT/JP2023/009051, filed on Mar. 9, 2023.

(30) Foreign Application Priority Data
Mar. 28, 2022 (JP) 2022-051550

(51) Int. Cl. C23F 11/12; C23F 11/04

(52) U.S. Cl. CPC C23F 11/124; C23F 11/04

(57) ABSTRACT

An object of the present invention is to provide a treatment liquid that has excellent removability of a metal part and suppressed dissolution of an insulating film in a case of being applied to an object to be treated, including the insulating film and the metal part. The treatment liquid of an embodiment of the present invention includes water, a fluoride source, periodic acid or a salt thereof, and a surfactant, and satisfies at least one of the following requirement A, the following requirement B, or the following requirement C.

Requirement A: The surfactant includes a cationic surfactant and has a predetermined aliphatic hydrocarbon group, and the cationic surfactant has a molecular weight of 300 or less.

Requirement B: The surfactant includes an anionic surfactant, the anionic surfactant has a predetermined group, and a mass ratio of a content of the anionic surfactant to a content of the fluoride source is 0.01 to 0.5.

Requirement C: The surfactant includes a nonionic surfactant, and the nonionic surfactant does not have a fluorine atom and is represented by a predetermined formula.

### CROSS-REFERENCE TO RELATED APPLICATIONS

This application is a Continuation of PCT International Application No. PCT/JP2023/009051 filed on Mar. 9, 2023, which claims priority under 35 U.S.C. § 119 (a) to Japanese Patent Application No. 2022-051550 filed on Mar. 28, 2022. The above applications are hereby expressly incorporated by reference, in their entirety, into the present application.

### BACKGROUND OF THE INVENTION

### 1. Field of the Invention

The present invention relates to a treatment liquid, a treatment method, and a method for manufacturing an electronic device.

### 2. Description of the Related Art

As the miniaturization of semiconductor products proceeds, there is an increasing demand for performing a step of removing unnecessary residues on a substrate in a process for manufacturing a semiconductor with high efficiency and high accuracy. Examples of the step include a method using a treatment liquid.

JP2018-032781A discloses an etchant (treatment liquid) including a predetermined amount of hydrofluoric acid and a predetermined amount of periodic acid.

### SUMMARY OF THE INVENTION

Examples of an object to be treated with a treatment liquid include an object to be treated, including an insulating film and a metal part (residue), and there is a demand for removing the metal part without dissolving the insulating film.

In a case where the present inventors have applied the treatment liquid described in JP2018-032781A to an object to be treated, including an insulating film and a metal part (residue), the removability of the metal part was excellent, whereas the insulating film was dissolved and a further improvement was required.

Therefore, an object of the present invention is to provide a treatment liquid that has excellent removability of a metal part and suppressed dissolution of an insulating film in a case of being applied to an object to be treated, including the insulating film and the metal part.

In addition, another object of the present invention is to provide a method for treating an object to be treated, using the treatment liquid, and a method for manufacturing an electronic device.

The present inventors have conducted studies to accomplish the objects, and as a result, have completed the present invention. That is, the present inventors have found that the objects can be accomplished by the following configurations.

[1] A treatment liquid for a semiconductor substrate, the treatment liquid comprising: water;
a fluoride source;
periodic acid or a salt thereof; and
a surfactant,
in which the treatment liquid satisfies at least one of the following requirement A, requirement B, or requirement C.

Requirement A: The surfactant includes a cationic surfactant, and the cationic surfactant has a monovalent aliphatic hydrocarbon group having 6 or more carbon atoms or a divalent aliphatic hydrocarbon group having 6 or more carbon atoms, and has a molecular weight of 300 or less.

Requirement B: The surfactant includes an anionic surfactant, and the anionic surfactant has one or more groups selected from the group consisting of a phosphoric acid group, a carboxy group, a sulfo group, and salts thereof, and has a mass ratio of a content of the anionic surfactant to a content of the fluoride source of 0.01 to 0.5.

Requirement C: The surfactant includes a nonionic surfactant, and the nonionic surfactant does not have a fluorine atom and is represented by Formula (C1), (C2), or (C3) which will be described later.

[2] The treatment liquid for a semiconductor substrate according to [1], in which the treatment liquid satisfies the requirement A.

[3] The treatment liquid for a semiconductor substrate according to [1], in which the treatment liquid satisfies the requirement B.

[4] The treatment liquid for a semiconductor substrate according to [1], in which the treatment liquid satisfies the requirement C.

[5] The treatment liquid for a semiconductor substrate according to any one of [1] to [4],
in which the treatment liquid substantially does not include insoluble particles.

[6] The treatment liquid for a semiconductor substrate according to any one of [1] to [5],
in which the treatment liquid does not include a silicon-containing compound.

[7] The treatment liquid for a semiconductor substrate according to any one of [1] to [6],
in which a content of the surfactant is 0.0001% to 0.5% by mass with respect to a total mass of the treatment liquid.

[8] The treatment liquid for a semiconductor substrate according to any one of [1] to [7], further comprising:
one or more kinds of pH adjusters selected from the group consisting of ammonia, a tetramethylammonium salt, a tetraethylammonium salt, a tetrapropylammonium salt, a tetrabutylammonium salt, an ethyltrimethylammonium salt, a triethylmethylammonium salt, and a diethyldimethylammonium salt.

[9] The treatment liquid for a semiconductor substrate according to any one of [1] to [8], further comprising:
a corrosion inhibitor.

[10] The treatment liquid for a semiconductor substrate according to any one of [1] to [9],
in which the treatment liquid is used as a cleaning liquid, an etchant, or a resist stripper.

[11] A method for treating an object to be treated, comprising:
a step of bringing an object to be treated, having a metal part and an insulating film, and the treatment liquid according to any one of [1] to into contact with each other.

[12] A method for manufacturing an electronic device, comprising:
the method for treating an object to be treated according to [11].

According to the present invention, it is possible to provide a treatment liquid that has excellent removability of a metal part and suppressed dissolution of an insulating film in a case of being applied to an object to be treated, including the insulating film and the metal part.

In addition, the present invention can provide a method for treating an object to be treated, using the treatment liquid, and a method for manufacturing an electronic device.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

Hereinafter, the meaning of each description in the present specification will be described.

In the present specification, a numerical range represented by “to” means a range including numerical values before and after “to” as a lower limit value and an upper limit value.

In the present specification, ppm is an abbreviation for “parts per million” and means 10⁻⁶. In addition, in the present specification, ppb is an abbreviation for “parts per billion” and means 10⁻⁹.

In the present specification, in a case where there are two or more components corresponding to a certain component, the “content” of such a component means a total content of the two or more components.

“Preparation” includes the preparation of a specific material by synthesis, mixing, or the like and the preparation of a predetermined substance by purchase or the like.

A compound described in the present specification may include structural isomers (compounds having the same number of atoms and different structures), optical isomers, and isotopes unless otherwise specified. In addition, one kind or plural kinds of the isomers and isotopes may be included.

### <Treatment Liquid>

The treatment liquid for a semiconductor substrate according to an embodiment of the present invention (hereinafter also simply referred to as a “treatment liquid”) includes water, a fluoride source, periodic acid or a salt thereof, and a surfactant, and satisfies at least one of a requirement A, a requirement B, or a requirement C, each of which will be described later.

A mechanism by which the treatment liquid of the embodiment of the present invention has excellent removability of a metal part and suppressed dissolution of an insulating film in a case of being applied to an object to be treated, including the insulating film and the metal part, is not necessarily clear, but has been presumed to be as follows by the present inventors.

By configuring the treatment liquid of the embodiment of the present invention to include water, the fluoride source, and periodic acid or a salt thereof, it is possible to exhibit a dissolving ability for the metal part, and thus to remove the metal part. On the other hand, by providing the treatment liquid with the configuration, it is also possible to exhibit a dissolving ability for the insulating film. It is considered that even in a case where the metal part is adjacent to the insulating film, the configuration of the treatment liquid enables the treatment liquid to have a dissolving ability for the metal part and the insulating film, and therefore, the removability of the metal part is more excellent.

In addition, by configuring the treatment liquid of the embodiment of the present invention to include a surfactant, it is possible to protect the surface of the insulating film and the metal part. Here, it is considered that in a case where the treatment liquid of the embodiment of the present invention satisfies at least one of the following requirements A, B, or C, the surfactant protects the surface of the insulating film more easily than the surface of the metal part, and has suppressed dissolution of the insulating film.

Further, by configuring the treatment liquid of the embodiment of the present invention to include the surfactant, the surfactant can coat the surface of the insulating film to improve wettability with respect to the treatment liquid. In this case, even in a case where the object to be treated has a recessed part, the treatment liquid is likely to reach the recessed part and the removability of the metal part can be further improved.

As a result, it is considered that the treatment liquid of the embodiment of the present invention has excellent removability of a metal part and suppressed dissolution of an insulating film in a case of being applied to an object to be treated, including the insulating film and the metal part.

Hereinafter, the components of the treatment liquid of the embodiment of the present invention will be described.

Furthermore, a notion that the removability of a metal part is excellent in a case where the treatment liquid is applied to an object to be treated, including the insulating film and the metal part, will hereinafter also be simply referred to as “the removability of the metal part is excellent”.

In addition, a notion that the dissolution of the insulating film is suppressed in a case where the treatment liquid is applied to an object to be treated, including the insulating film and the metal part, will hereinafter also be simply referred to as “the dissolution of the insulating film is suppressed”.

### [Water]

The treatment liquid of the embodiment of the present invention includes water.

As the water, water that has undergone a purification treatment, such as distilled water, deionized water, and ultrapure water, is preferable, and ultrapure water used for manufacturing semiconductors, is more preferable. The water included in the treatment liquid may include a trace amount of inevitable mixing component.

A content of water with respect to a total mass of the treatment liquid is preferably 50% by mass or more, more preferably 65% by mass or more, and still more preferably 75% by mass or more. An upper limit thereof is not particularly limited, and is preferably 99.999% by mass or less, more preferably 99.9% by mass or less, and still more preferably 99% by mass or less with respect to the total mass of the treatment liquid.

### [Fluoride Source]

The treatment liquid of the embodiment of the present invention includes a fluoride source.

The fluoride source refers to a compound that can supply a fluoride ion.

The fluoride source is generally a compound that includes a fluoride ion and a cation.

Examples of the fluoride ion include a fluoride ion (F⁻), a bifluoride ion (HF₂⁻), and a fluoride-containing ion (for example, MF₆ⁿ⁻, MF₄ⁿ⁻, M: any atom, and n: 1 to 3). Examples of M include boron (B), aluminum (Al), phosphorus (P), titanium (Ti), zirconium (Zr), niobium (Nb), antimony (Sb), and tantalum (Ta).

Examples of the cation include H⁺, Li⁺, Na⁺, K⁺, and NH₄⁺, and H⁺ or NH₄⁺ is preferable.

Among the fluoride sources, the fluoride source preferably includes a compound selected from the group consisting of hydrogen fluoride (HF), hexafluorotitanic acid (H₂TiF₆), hexafluorozirconic acid (H₂ZrF₆), hexafluororhenic acid (HPF₆), tetrafluoroboric acid (HBF₄), and ammonium hydrogen fluoride (NH₄F).

A content of the fluoride source is preferably 0.001% to 5.00% by mass, more preferably 0.01% to 1.00% by mass, and still more preferably 0.05% to 0.50% by mass with respect to the total mass of the treatment liquid.

The fluoride source may be used alone or in combination of two or more kinds thereof.

In a case where two or more kinds of the fluoride sources are used, a total amount thereof is preferably in the preferred content ranges.

An aqueous solution of the fluoride source may be used as the fluoride source. In a case where the aqueous solution is used, the content of the fluoride source indicates the content of the fluoride source obtained by removing water from the aqueous solution.

### [Periodic Acid or Salt Thereof]

The treatment liquid of the embodiment of the present invention includes periodic acid or a salt thereof.

The periodic acid may be orthoperiodic acid (H₅IO₆) or metaperiodic acid (HIO₄), or may be either of these. In addition, examples of the cation constituting the salt of the periodic acid include Na⁺ and K⁺. That is, examples of the salt of periodic acid include a sodium salt of the periodic acid (for example, Na₂H₃IO₆) and a potassium salt of the periodic acid (for example, K₂H₃IO₆).

Among these, the periodic acid or a salt thereof is preferably orthoperiodic acid or metaperiodic acid.

From the viewpoint that the removability of the metal part is more excellent, a content of the periodate or a salt thereof is preferably 0.01% to 10.0% by mass, more preferably 0.1% to 5.0% by mass, and still more preferably 0.5% to 3.0% by mass with respect to the total mass of the treatment liquid.

The periodic acid or salt thereof may be used alone or in combination of two or more kinds thereof.

In a case where two or more kinds of the periodic acids or salts thereof are used, a total amount thereof is preferably in the preferred content ranges.

### [Surfactant]

The treatment liquid of the embodiment of the present invention includes a surfactant, and satisfies at least one of the following requirement A, the following requirement B, or the following requirement C with regard to the surfactant.

Requirement A: The surfactant includes a cationic surfactant, and the cationic surfactant has a monovalent aliphatic hydrocarbon group having 6 or more carbon atoms or a divalent aliphatic hydrocarbon group having 6 or more carbon atoms, and has a molecular weight of 300 or less.

Requirement B: The surfactant includes an anionic surfactant, and the anionic surfactant has one or more groups selected from the group consisting of a phosphoric acid group (—PO₄H₂), a carboxy group, a sulfo group, and salts thereof, and has a mass ratio of a content of the anionic surfactant to a content of the fluoride source of 0.01 to 0.5.

Requirement C: The surfactant includes a nonionic surfactant, and the nonionic surfactant does not have a fluorine atom and is represented by Formula (C1), (C2), or (C3) which will be described later.

Furthermore, the surfactant refers to a compound having a hydrophilic moiety and a hydrophobic moiety.

Hereinafter, each of the requirement will be described.

### (Requirement A)

In the requirement A, the surfactant includes a cationic surfactant, and the cationic surfactant has a monovalent aliphatic hydrocarbon group having 6 or more carbon atoms or a divalent aliphatic hydrocarbon group having 6 or more carbon atoms, and has a molecular weight of 300 or less.

Furthermore, the molecular weight of 300 or less refers to a molecular weight including an anion in a case where the cationic surfactant is a salt with an anion. A lower limit of the molecular weight of the cationic surfactant is not particularly limited, but is preferably 90 or more, more preferably 170 or more, and still more preferably 200 or more.

The cationic surfactant refers to a surfactant having at least one of a group having a cationic structure or a group having a structure that can be cationized. Furthermore, the structure that can be cationized refers to a structure that can be cationized in the treatment liquid.

Moreover, in the cationic surfactant, a group having a cationized structure can function as the hydrophilic moiety. In addition, in the cationic surfactant, a monovalent aliphatic hydrocarbon group having 6 or more carbon atoms or a divalent aliphatic hydrocarbon group having 6 or more carbon atoms can function as the hydrophobic moiety.

The number of the groups having a cationized structure contained in the cationic surfactant is preferably 1 to 3, and more preferably 1 or 2.

As the cationized structure, a structure including a nitrogen atom is preferable.

As the cationized structure, structures represented by Formulae (1) to (4) are preferable.

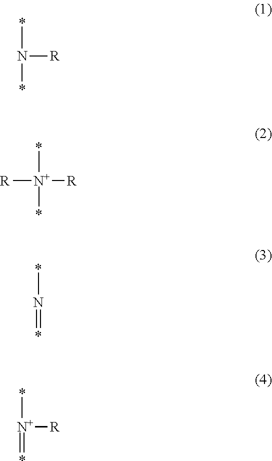

In Formulae (1) to (4), * represents a bonding position.

In Formula (1), Formula (2), and Formula (4), R's each independently represent a hydrogen atom or a monovalent substituent.

Examples of the monovalent substituent represented by R include an alkyl group and an aryl group.

The alkyl group which may have a substituent may be cyclic or chained. The cyclic alkyl group which may have a substituent may be a monocycle or a polycycle. The chain alkyl group which may have a substituent may be linear or branched.

The cyclic alkyl group (cycloalkyl group) which may have a substituent preferably has 4 to 10 carbon atoms, and more preferably has 4 to 6 carbon atoms.

The chain-like alkyl group which may have a substituent preferably has 1 to 4 carbon atoms, and more preferably has 1 or 2 carbon atoms.

Examples of the substituent of the alkyl group which may have a substituent include a halogen atom, a hydroxy group, an alkyl group which may have a substituent, and an aryl group which may have a substituent. In addition, a methylene group constituting the alkyl group which may have a substituent may be substituted with —O—, —S—, —CO—, —COO—, —CONH—, —SO₂—, or a divalent linking group such as Formulae (1) to (4).

The aryl group which may have a substituent may be a heteroaryl group including an atom other than a carbon atom in a ring member. The aryl group which may have a substituent may be a polycycle or a monocycle. The number of ring member atoms of the aryl group which may have a substituent is preferably 5 to 10, and more preferably 5 to 8.

Examples of the substituent of the aryl group which may have a substituent include the same ones as those of the substituent of the alkyl group which may have a substituent, and the halogen atom, the hydroxy group, or the alkyl group which does not have a substituent is preferable.

In addition, two bonding positions in Formulae (1) to (4), or one bonding position and R may be bonded to another linking group to form a ring. The ring thus formed may or may not have aromaticity as a whole.

Examples of the group including the structure represented by Formula (1) include a primary amino group, a secondary amino group, and a tertiary amino group (including a pyrrolidino group, a piperidino group, a morpholino group, and the like).

Examples of the group including the structure represented by Formula (2) include a quaternary ammonium group.

Examples of the group including the structure represented by Formula (3) include an imino group, a guanidino group, a biguanidino group, a pyrazole ring group, an imidazole ring group, a pyridine ring group, a benzimidazole ring group, and a benzotriazole ring group.

Examples of the group including the structure represented by Formula (4) include a group in which a nitrogen atom of the group including the structure represented by Formula (3) is quaternized.

Examples of the monovalent aliphatic hydrocarbon group having 6 or more carbon atoms include a linear or branched alkyl group having 6 or more carbon atoms and an alkyl group having a cyclic structure and having 6 or more carbon atoms.

The monovalent aliphatic hydrocarbon group having 6 or more carbon atoms preferably has 6 to 18 carbon atoms, more preferably has 8 to 14 carbon atoms, and still more preferably has 10 to 14 carbon atoms.

It should be noted that the monovalent aliphatic hydrocarbon group having 6 or more carbon atoms is selected such that the molecular weight of the cationic surfactant is 300 or less.

Examples of the linear or branched alkyl group having 6 or more carbon atoms include a hexyl group, a heptyl group, an octyl group, a nonyl group, a decyl group, an undecyl group, a dodecyl group, a tridecyl group, a tetradecyl group, a pentadecyl group, and a hexadecyl group.

Examples of the alkyl group having a cyclic structure having 6 or more carbon atoms include a cyclohexyl group, a 4-methylcyclohexyl group, a 4-isopropylcyclohexyl group, and a 4-hexylcyclohexyl group.

As the monovalent aliphatic hydrocarbon group having 6 or more carbon atoms, a linear alkyl group having 6 or more carbon atoms is preferable. The number of carbon atoms in the linear alkyl group having 6 or more carbon atoms is also preferably the preferred number of carbon atoms.

Examples of the divalent aliphatic hydrocarbon group having 6 or more carbon atoms include a linear alkylene group having 6 or more carbon atoms, a branched alkylene group having 6 or more carbon atoms, and an alkylene group having a cyclic structure and having 6 or more carbon atoms.

The divalent aliphatic hydrocarbon group having 6 or more carbon atoms preferably has 6 to 14 carbon atoms, more preferably has 6 to 12 carbon atoms, and still more preferably has 6 to 10 carbon atoms.

It should be noted that the divalent aliphatic hydrocarbon group having 6 or more carbon atoms is selected such that the molecular weight of the cationic surfactant is 300 or less.

Examples of the linear or branched alkylene group having 6 or more carbon atoms include a hexylene group, a heptylene group, an octylene group, a nonylene group, a decylene group, an undecylene group, a dodecylene group, a tridecylene group, and a tetradecylene group.

Examples of the alkylene group having a cyclic structure having 6 or more carbon atoms include a group obtained by removing one hydrogen atom from the alkyl group having a cyclic structure having 6 or more carbon atoms.

As the divalent aliphatic hydrocarbon group having 6 or more carbon atoms, a linear alkylene group having 6 or more carbon atoms is preferable. The number of carbon atoms in the linear alkylene group having 6 or more carbon atoms is also preferably the preferred number of carbon atoms.

The cationic surfactant is preferably a compound in which a group including a structure represented by Formulae (1) to (4) and a monovalent aliphatic hydrocarbon group having 6 or more carbon atoms or a divalent aliphatic hydrocarbon group having 6 or more carbon atoms are bonded to each other.

Among these, the cationic surfactant is preferably a compound represented by Formulae (A1) to (A5).

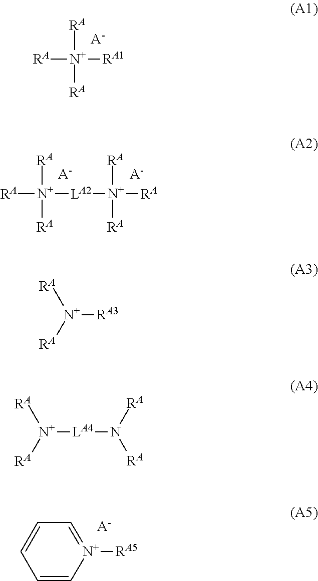

In Formula (A1), R^{A}'s each independently represent an alkyl group having 1 or 2 carbon atoms. Examples of the alkyl group represented by R^{A} include a methyl group and an ethyl group, and the methyl group is preferable.

In Formula (A1), R^{A1} represents a monovalent aliphatic hydrocarbon group having 6 or more carbon atoms, and is preferably a linear alkyl group having 6 or more carbon atoms. A preferred aspect of the linear alkyl group having 6 or more carbon atoms is as described above.

In Formula (A1), A⁻ represents a monovalent anion. Examples of the monovalent anion represented by A⁻ include a hydroxide ion, a halogen ion (for example, Cl⁻ and Br⁻), a nitrate ion, and an acetate ion, the hydroxide ion or the halogen ion is preferable, and Cl⁻ is more preferable.

Examples of the compound represented by Formula (A1) include an alkyltrimethylammonium salt. It should be noted that the alkyl group contained in the compound has 6 or more carbon atoms.

More specific examples of the compound represented by Formula (A1) include octyltrimethylammonium chloride, decyltrimethylammonium chloride, dodecyltrimethylammonium chloride, and dodecyltrimethylammonium hydroxide.

In Formula (A2), R^{A}'s each independently represent an alkyl group having 1 or 2 carbon atoms. The alkyl group having 1 or 2 carbon atoms represented by R^{A} is the same as the aspect of Formula (A1).

In Formula (A2), L^{A2} represents a divalent aliphatic hydrocarbon group having 6 or more carbon atoms, and is preferably a linear alkylene group having 6 or more carbon atoms. A preferred aspect of the linear alkylene group having 6 or more carbon atoms is as described above.

In Formula (A2), A-represents a monovalent anion. The monovalent anion represented by A is the same as in the aspect of Formula (A1).

Examples of the compound represented by Formula (A2) include a hexamethylalkylene diammonium salt. It should be noted that the alkylene group included in the compound has 6 or more carbon atoms.

More specific examples of the compound represented by Formula (A2) include hexamethonium dichloride and hexamethonium hydroxide.

In Formula (A3), R^{A}'s each independently represent an alkyl group having 1 or 2 carbon atoms. The alkyl group having 1 or 2 carbon atoms represented by R^{A} is the same as the aspect of Formula (A1).

In Formula (A3), R^{A3} represents a monovalent aliphatic hydrocarbon group having 6 or more carbon atoms, and is preferably a linear alkyl group having 6 or more carbon atoms. A preferred aspect of the linear alkyl group having 6 or more carbon atoms is as described above.

Examples of the compound represented by Formula (A3) include an alkyl dimethylammonium salt. It should be noted that the alkyl group contained in the compound has 6 or more carbon atoms.

More specific examples of the compound represented by Formula (A3) include N,N-dimethylhexylamine, N,N-dimethyloctylamine, N,N-dimethyldecylamine, N,N-dimethyldodecylamine, and N,N-dimethyltetradecylamine.

In Formula (A4), R^{A}'s each independently represent an alkyl group having 1 or 2 carbon atoms. The alkyl group having 1 or 2 carbon atoms represented by R^{A} is the same as the aspect of Formula (A1).

In Formula (A4), L^{A4} represents a divalent aliphatic hydrocarbon group having 6 or more carbon atoms, and is preferably a linear alkylene group having 6 or more carbon atoms. A preferred aspect of the linear alkylene group having 6 or more carbon atoms is as described above.

Examples of the compound represented by Formula (A4) include tetramethylalkylenediamine. It should be noted that the alkylene group included in the compound has 6 or more carbon atoms.

Specific examples of the compound represented by Formula (A4) include N,N,N′,N′-tetramethylhexylenediamine, N,N,N′,N′-tetramethyloctylenediamine, N,N,N′,N′-tetramethyldecylenediamine, N,N,N′,N′-tetramethyldodecylenediamine, and N,N,N′,N′-tetramethyltetradecylenediamine.

In Formula (A5), R^{A5} represents a monovalent aliphatic hydrocarbon group having 6 or more carbon atoms, and is preferably a linear alkyl group having 6 or more carbon atoms. A preferred aspect of the linear alkyl group having 6 or more carbon atoms is as described above.

In Formula (A5), A-represents a monovalent anion. The monovalent anion represented by A⁻ is the same as in the aspect of Formula (A1).

Examples of the compound represented by Formula (A5) include an alkylpyridinium salt. It should be noted that the alkyl group contained in the compound has 6 or more carbon atoms.

More specific examples of the compound represented by Formula (A5) include hexylpyridinium chloride, octylpyridinium chloride, decylpyridinium chloride, dodecylpyridinium chloride, and dodecylpyridinium hydroxide.

Among the compounds, the compound represented by Formula (A1), Formula (A2), or Formula (A5) is preferable. A preferred aspect thereof is as described in each formula.

As the cationic surfactant, a commercially available product may be used.

In a case where the requirement A is satisfied, a content of the cationic surfactant is preferably 0.0001% to 0.5% by mass, more preferably 0.001% to 0.5% by mass, and still more preferably 0.005% to 0.1% by mass with respect to the total mass of the treatment liquid.

The cationic surfactant may be used alone or in combination of two or more kinds thereof.

In a case where two or more kinds of the cationic surfactants are used, a total amount thereof is preferably in the preferred content ranges.

In a case where the requirement A is satisfied, a mass ratio of the content of the cationic surfactant to the content of the fluoride source is preferably 0.01 to 1.0, more preferably 0.01 to 0.5, still more preferably 0.1 to 0.5, and particularly preferably 0.1 to 0.2.

In a case where the requirement A is satisfied, a mass ratio of the cationic surfactant to the periodic acid or a salt thereof is preferably 0.1 to 10.0, more preferably 0.1 to 5.0, still more preferably 1.0 to 5.0, and particularly preferably 1.0 to 2.0.

### (Requirement B)

In the requirement B, the surfactant includes an anionic surfactant, and the anionic surfactant has one or more groups selected from the group consisting of a phosphoric acid group, a carboxy group, a sulfo group, and salts thereof, and has a mass ratio of a content of the anionic surfactant to a content of the fluoride source of 0.01 to 0.5.

The anionic surfactant refers to a surfactant having at least one of a group having an anionized structure or a group having a structure that can be anionized. Furthermore, the structure that can be anionized refers to a structure that can be anionized in the treatment liquid.

Moreover, in the anionic surfactant, a group having an anionized structure functions as a hydrophilic moiety, and one or more groups selected from the group consisting of a phosphoric acid group, a carboxy group, a sulfo group, and a salt thereof correspond to the anionized structure. As the anionized structure, a phosphoric acid group or a salt thereof, a carboxy group, or a sulfo group or a salt thereof is preferable, the phosphoric acid group or a salt thereof, or the sulfo group or a salt thereof is more preferable, and the sulfo group or a salt thereof is still more preferable.

The number of one or more groups selected from the group consisting of a phosphoric acid group, a carboxy group, a sulfo group, and salts thereof, which are contained in the anionic surfactant, is preferably 1 to 3, more preferably 1 or 2, and still more preferably 1.

A molecular weight of the anionic surfactant is preferably 130 to 500, more preferably 200 to 400, and still more preferably 200 to 300.

Furthermore, in a case where the anionic surfactant is a salt with a cation, the molecular weight of the anionic surfactant refers to a molecular weight including the cation.

It is preferable that the anionic surfactant has a hydrocarbon group having 6 or more carbon atoms, which may have a substituent, as a hydrophobic moiety. As the substituent, a halogen atom is preferable. Examples of the hydrocarbon group include an alkyl group, an aryl group, and a group formed by a combination thereof.

The aryl group is also preferably a hydrocarbon aromatic ring group consisting of carbon and hydrogen. Examples of the aryl group include a phenyl group and a naphthyl group.

The alkyl group may be linear or branched, and may have a cyclic structure. Examples of the cyclic structure of the alkyl group include a cyclobutane ring, a cyclopentane ring, and a cyclohexane ring.

Preferred examples of the hydrocarbon group having 6 or more carbon atoms, which may have a substituent, include a linear alkyl group, a branched alkyl group, an aryl group, -arylene group-linear alkyl group, -arylene group-branched alkyl group, -linear alkylene group-phenyl group, -cyclic alkylene group-linear alkyl group, and -cyclic alkylene group-branched alkyl group.

The hydrocarbon group having 6 or more carbon atoms, which may have a substituent, preferably has 6 to 20 carbon atoms, more preferably has 8 to 18 carbon atoms, and still more preferably has 10 to 16 carbon atoms.

Among these, the anionic surfactant is preferably a compound represented by Formula (B1).

R^{B1}-L^{B1}-X Formula (B1)

In Formula (B1), X represents one or more groups selected from the group consisting of a phosphoric acid group, a carboxy group, a sulfo group, and a salt thereof. The group represented by X is preferably the phosphoric acid group or a salt thereof, the carboxy group, or the sulfo group or a salt thereof, more preferably the phosphoric acid group or a salt thereof, or the sulfo group or a salt thereof, and still more preferably the sulfo group or a salt thereof.

In Formula (B1), L^{B1} represents a single bond or a divalent linking group. As the divalent linking group, —O— is preferable.

In Formula (B1), R^{B1} represents a group constituting a hydrophobic moiety, and is preferably a hydrocarbon group having 6 or more carbon atoms, which may have a substituent. The aspect of the hydrocarbon group having 6 or more carbon atoms, which may have a substituent, is as described above. Among these, as the group constituting the hydrophobic moiety represented by R^{B1}, a linear alkyl group or a branched alkyl group is preferable, and the linear alkyl group is more preferable. The linear alkyl group preferably has 6 to 20 carbon atoms, more preferably has 8 to 18 carbon atoms, and still more preferably has 10 to 16 carbon atoms. Examples of the linear alkyl group include a decyl group, an undecyl group, a dodecyl group, a tridecyl group, a tetradecyl group, a pentadecyl group, and a hexadecyl group.

Examples of the compound represented by Formula (B1) include decylphosphoric acid, dodecylphosphoric acid, sodium dodecylphosphate, dodecanoic acid, tridecanoic acid, sodium tridecylphosphate, 1-dodecanesulfonic acid, sodium 1-dodecanesulfonate, dodecyl sulfate, sodium dodecyl sulfate, and potassium dodecyl sulfate.

As the anionic surfactant, a commercially available product may be used.

Examples of a commercially available nonionic surfactant include “NIKKOL HOSTEN HLP” manufactured by Nikko Chemicals Co., Ltd.

In the requirement B, a mass ratio of the content of the cationic surfactant to the content of the fluoride source is 0.01 to 0.5. It is considered that by setting the ratio to be in the ranges, the removability of the metal part is excellent and the dissolution of the insulating film is suppressed. The ratio is preferably 0.1 to 0.5.

In a case where the requirement B is satisfied, a content of the anionic surfactant is preferably 0.0001% to 0.5% by mass, more preferably 0.001% to 0.1% by mass, and still more preferably 0.002% to 0.0045% by mass with respect to the total mass of the treatment liquid.

The anionic surfactant may be used alone or in combination of two or more kinds thereof.

In a case where two or more kinds of the anionic surfactants are used, a total amount thereof is preferably in the preferred content ranges.

In a case where the requirement B is satisfied, a mass ratio of the anionic surfactant to the periodic acid or a salt thereof is preferably 0.1 to 5.0, and more preferably 1.0 to 5.0.

### (Requirement C)

In the requirement C, the surfactant includes a nonionic surfactant, and the nonionic surfactant does not have a fluorine atom and is represented by Formula (C1), (C2), or (C3).

R^{C1}—(O—CH₂—CH₂)_{nC1}—OH Formula (C1)

R^{C2}—(O—C₃H₆)_{nC2}—OH Formula (C2)

R^{C3}—(O—C₃H₆)_{mC3}—(O—CH₂—CH₂)_{nC3}—OH Formula (C3)

Hereinafter, each of the formulae will be described.

In Formula (C1), R^{C1} represents a hydrocarbon group which does not include a fluorine atom and may have a substituent. Examples of R^{C1} include a hydrocarbon group having 6 or more carbon atoms, which may have a substituent, as a hydrophobic moiety, described in the anionic surfactant. Among these, as the group represented by R^{C1}, for example, a linear alkyl group, -arylene group-linear alkyl group, -arylene group-branched alkyl group, -cyclic alkylene group-linear alkyl group, or -cyclic alkylene group-branched alkyl group is preferable, the linear alkyl group, -arylene group-linear alkyl group, or -arylene group-branched alkyl group is more preferable, and the linear alkyl group or -arylene group-branched alkyl group is still more preferable. The group represented by R^{C1} preferably has 6 to 20 carbon atoms, more preferably has 8 to 18 carbon atoms, and still more preferably has 10 to 16 carbon atoms.

Examples of the linear alkyl group represented by R^{C1} include a decyl group, an undecyl group, a dodecyl group, a tridecyl group, a tetradecyl group, a pentadecyl group, and a hexadecyl group.

Examples of the -arylene group-branched alkyl group represented by R^{C1} include a 4-isopropylphenyl group, a 4-tert-butylphenyl group, a 4-(1,1,3,3-tetramethylbutyl)phenyl group, and a 4-(2-ethylhexyl)phenyl group.

In Formula (C1), nC1 represents an integer of 1 or more. nC1 is preferably 4 or more, more preferably 7 or more, and still more preferably 9 or more. An upper limit thereof may be, for example, 50 or less.

In Formula (C2), R^{C2} represents a hydrocarbon group which does not include a fluorine atom and may have a substituent. Examples of the group represented by R^{C2} include the same groups as those of the group represented by R^{C1}, and preferred aspects thereof are also the same.

In Formula (C2), the —C₃H₆— moiety (propylene group) in the repeating unit represented by —(O—C₃H₆)_{nC2}— may be linear (—CH₂—CH₂—CH₂—) or branched (—CHCH₃—CH₂—). In a case where the repeating units are present in a plural number, the propylene groups may be all linear or all branched, or may include both the forms.

In Formula (C2), nC2 represents an integer of 1 or more. nC2 represents the number of the repeating units, and nC2 is preferably 4 or more, more preferably 7 or more, and still more preferably 9 or more. An upper limit thereof may be, for example, 50 or less.

In Formula (C3), R^{C3} represents a hydrocarbon group which does not include a fluorine atom and may have a substituent. Examples of the group represented by R^{C3} include the same groups as those represented by R^{C1}, and preferred aspects thereof are also the same.

In Formula (C3), the —C₃H₆— moiety (propylene group) in the repeating unit represented by —(O—C₃H₆)_{mC3}— may be linear (—CH₂—CH₂—CH₂—) or branched (—CHCH₃—CH₂—). In a case where the repeating units are present in a plural number, the propylene groups may be all linear or all branched, or may include both the forms.

In Formula (C3), nC3 and mC3 each represent an integer of 1 or more. nC3 and mC3 each represent the number of repeating units included in the molecule, and the same type of repeating units may be continuously bonded, may be alternately bonded, or may be randomly bonded. In addition, blocks in which the same type of repeating units are continuously bonded may be alternately bonded. nC3 is preferably 2 or more, and more preferably 5 or more. A sum of nC3 and mC3 is preferably 4 or more, and more preferably 7 or more. An upper limit of the sum of nC3 and mC3 may be, for example, 50.

From the viewpoint that the removability of the metal part is more excellent, a hydrophilic-lipophilic balance (HLB) value of the nonionic surfactant is preferably 10.0 or more, more preferably 12.0 or more, still more preferably 13.0 or more, and particularly preferably 17.5 or more. Examples of an upper limit thereof include 20.0.

Furthermore, the HLB value is a value representing a degree of affinity of the surfactant for water and water-insoluble organic compounds. Typically, the HLB value is defined by Expression (G).

HLB value=20×Formula weight of hydrophilic part of surfactant/Molecular weight of surfactant Expression (G):

As the nonionic surfactant, a commercially available product may be used.

Examples of the commercially available nonionic surfactant include EMULGEN™ series (for example, 104P and LS-106) and TRITON™ series (for example, X-114, X-100, and X-405).

In a case where the requirement C is satisfied, a content of the nonionic surfactant is preferably 0.0001% to 0.5% by mass, more preferably 0.001% to 0.1% by mass, and still more preferably 0.005% to 0.05% by mass with respect to the total mass of the treatment liquid.

The nonionic surfactant may be used alone or in combination of two or more kinds thereof.

In a case where two or more kinds of the nonionic surfactants are used, a total amount thereof is preferably in the preferred content ranges.

In a case where the requirement C is satisfied, a mass ratio of the content of the nonionic surfactant to the content of the fluoride source is preferably 0.01 to 1.0, more preferably 0.02 to 0.5, still more preferably 0.05 to 0.5, and particularly preferably 0.1 to 0.2.

In a case where the requirement C is satisfied, a mass ratio of the nonionic surfactant to the periodic acid or a salt thereof is preferably 0.1 to 10.0, more preferably 0.2 to 5.0, still more preferably 0.5 to 5.0, and particularly preferably 1.0 to 2.0.

The surfactant may satisfy at least one of the requirement A, the requirement B, or the requirement C, but may satisfy two or more of the requirements.

In this case, a total content of the surfactants is preferably 0.0001% to 0.5% by mass, more preferably 0.001% to 0.1% by mass, and still more preferably 0.005% to 0.05% by mass with respect to the total mass of the treatment liquid.

### [Insoluble Particles]

It is preferable that the treatment liquid of the embodiment of the present invention substantially does not include insoluble particles.

The “insoluble particles” are particles of an inorganic solid, an organic solid, and the like, and correspond to particles which are present as particles without being finally dissolved in the treatment liquid.

The expression that “the insoluble particles are substantially not included” means that the number of particles having a particle diameter of 50 nm or more included in 1 mL of a composition for measurement is 40,000 or less in a case where the treatment liquid is diluted 10,000 times with the solvent included in the treatment liquid to obtain the composition for measurement. Furthermore, the number of the particles included in the composition for measurement can be measured in a liquid phase using a commercially available particle counter. As a commercially available particle counter device, a device manufactured by RION Co., Ltd. or PMS Co., Ltd. can be used. Representative examples of the device of the former include KS-19F, and representative examples of the device of the latter include Chem20. In order to measure larger particles, a device such as KS-42 series or LiQuilaz II S series can be used.

Examples of the insoluble particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

Examples of a method for removing the insoluble particles from the treatment liquid include a purification treatment such as filtering.

### [pH Adjuster]

The treatment liquid of the embodiment of the present invention may include a pH adjuster. The pH may be adjusted to a pH in a preferred range which will be described later, using the pH adjuster.

The pH adjuster is a compound different from the compound. Examples of the pH adjuster include an acidic compound and a basic compound.

### (Acidic Compound)

The acidic compound is an acidic compound that exhibits acidity (a pH of less than 7.0) in an aqueous solution.

Examples of the acidic compound include an inorganic acid, an organic acid, and salts thereof.

Examples of the inorganic acid include sulfuric acid, hydrochloric acid, nitric acid, and salts thereof.

Examples of the organic acid include carboxylic acid, sulfonic acid, and salts thereof.

Examples of the monocarboxylic acid include lower (1 to 4 carbon atoms) aliphatic monocarboxylic acids such as formic acid, acetic acid, propionic acid, and butyric acid, and salts thereof.

Examples of the sulfonic acid include methanesulfonic acid, benzenesulfonic acid, p-toluenesulfonic acid (tosylic acid), and salts thereof.

A content of the acidic compound is preferably 0.1% to 10.0% by mass, and more preferably 0.3% to 5.0% by mass with respect to the total mass of the treatment liquid.

The acidic compound may be used alone or in combination of two or more kinds thereof.

In a case where two or more kinds of the acidic compounds are used, a total amount thereof is preferably in the preferred content ranges.

### (Basic Compound)

The basic compound is a compound that exhibits alkalinity (a pH of more than 7.0) in an aqueous solution.

Examples of the basic compound include an organic base, an inorganic base, and salts thereof.

Examples of the inorganic base include ammonia, alkali metal hydroxides such as sodium hydroxide and potassium hydroxide, and alkaline earth metal hydroxides.

Examples of the organic base include an amine compound, a quaternary ammonium salt, an alkanolamine compound and a salt thereof, an amine oxide compound, a nitro compound, a nitroso compound, an oxime compound, a ketoxime compound, an aldoxime compound, a lactam compound, and an isocyanide compound. Furthermore, the amine compound means a compound that has an amino group in the molecule, in which the compound is not included in the alkanolamine, amine oxide compound, and lactam compound. Examples of the amine compound include a primary amine having a primary amino group (—NH₂) in the molecule, a secondary amine having a secondary amino group (>NH) in the molecule, and a tertiary amine having a tertiary amino group (>N—) in the molecule.

It should be noted that the organic base is a compound different from the cationic surfactant. That is, the organic base does not have a monovalent aliphatic hydrocarbon group having 6 or more carbon atoms or a divalent aliphatic hydrocarbon group having 6 or more carbon atoms.

As the organic base, the quaternary ammonium salt is preferable.

Examples of the quaternary ammonium salt include a tetramethylammonium salt, a tetraethylammonium salt, a tetrabutylammonium salt, an ethyltrimethylammonium salt, a triethylmethylammonium salt, a diethyldimethylammonium salt, a tributylmethylammonium salt, a dimethyldipropylammonium salt, a benzyltrimethylammonium salt, a benzyltriethylammonium salt, a (2-hydroxyethyl)trimethylammonium salt (also referred to as “choline”), a triethyl(2-hydroxyethyl) ammonium salt, a diethylbis(2-hydroxyethyl) ammonium salt, an ethyltris(2-hydroxyethyl) ammonium salt, and a tris(2-hydroxyethyl)methylammonium salt.

The anion include in the quaternary ammonium salt is preferably Cl⁻, Br⁻, or OH⁻, more preferably Cl⁻ or OH, and still more preferably OH⁻.

Among these, one or more kinds of basic compounds as the pH adjuster are preferably selected from the group consisting of ammonia, a tetramethylammonium salt, a tetraethylammonium salt, a tetrapropylammonium salt, a tetrabutylammonium salt, an ethyltrimethylammonium salt, a triethylmethylammonium salt, and a diethyldimethylammonium salt.

A content of the basic compound is preferably 0.1% to 10.0% by mass, and more preferably 0.3% to 5.0% by mass with respect to the total mass of the treatment liquid.

The basic compound may be used alone or in combination of two or more kinds thereof.

In a case where two or more kinds of the basic compounds are used, a total amount thereof is preferably in the preferred content ranges.

### [Corrosion Inhibitor]

The treatment liquid may include a corrosion inhibitor. It should be noted that the corrosion inhibitor is a compound different from the compound.

The corrosion inhibitor is added to the treatment liquid for the purpose of preventing etching of other materials present on an object to be treated.

The type of the corrosion inhibitor is appropriately selected depending on the material of other materials present in the object to be treated.

Examples of the corrosion inhibitor include an amine compound, an imine compound, a thiol compound, and a thioether compound. Among these, the corrosion inhibitor is preferably the imine compound, and more preferably an unsaturated heterocyclic compound including nitrogen.

Examples of the unsaturated heterocyclic compound including nitrogen include pyridine, triazine, imidazole, benzimidazole, triazole, benzotriazole, purine, xanthine, and derivatives thereof.

The content of the corrosion inhibitor is not particularly limited, but is preferably 0.1% by mass or more, and more preferably 1% by mass or more with respect to the total mass of the treatment liquid. An upper limit thereof is not particularly limited, but is preferably 10% by mass or less, and more preferably 5% by mass or less with respect to the total mass of the treatment liquid.

### [Silicon-Containing Compound]

It is preferable that the treatment liquid of the embodiment of the present invention does not include a silicon-containing compound.

Examples of the silicon-containing compound include an alkoxysilane compound, and specific examples thereof include tetramethoxysilane and tetraethoxysilane.

### [Other Additives]

The treatment liquid may include other additives, in addition to the above-described components.

Hereinafter, such other additives will be described.

### (Polyhydroxy Compound Having Molecular Weight of 500 or More)

The treatment liquid may include a polyhydroxy compound having a molecular weight of 500 or more.

The polyhydroxy compound is a compound different from the compound that can be included in the treatment liquid.

The polyhydroxy compound is an organic compound having 2 or more (for example, 2 to 200) alcoholic hydroxyl groups in one molecule.

A molecular weight (a weight-average molecular weight in a case of having a molecular weight distribution) of the polyhydroxy compound is 500 or more, preferably 500 to 100,000, and more preferably 500 to 3,000.

Examples of the polyhydroxy compound include polyoxyalkylene glycols such as polyethylene glycol, polypropylene glycol, and polyoxyethylene polyoxypropylene glycol; oligosaccharides such as manninotriose, cellotriose, gentianose, raffinose, melezitose, cellotetrose, and stachyose; and polysaccharides such as starch, glycogen, cellulose, chitin, and chitosan, and hydrolysates thereof.

Cyclodextrin is also preferable as the polyhydroxy compound.

The cyclodextrin means one kind of cyclic oligosaccharide having a cyclic structure in which a plurality of D-glucoses are bonded by a glucoside bond. A compound in which 5 or more (for example, 6 to 8) glucoses are bonded is known.

Examples of the cyclodextrin include α-cyclodextrin, β-cyclodextrin, and γ-cyclodextrin, and the γ-cyclodextrin is preferable.

The polyhydroxy compounds may be used alone or in combination of two or more kinds thereof.

The content of the polyhydroxy compound is preferably 0.01% to 10% by mass, more preferably 0.05% to 5% by mass, and still more preferably 0.1% to 3% by mass with respect to the total mass of the treatment liquid.

The content of the polyhydroxy compound is preferably 0.01% to 30% by mass, more preferably 0.05% to 25% by mass, and still more preferably 0.5% to 20% by mass with respect to a total mass of the components of the treatment liquid excluding the solvent.

### [Antibacterial Agent]

The treatment liquid may include an antibacterial agent.

The antibacterial agent is a compound different from the compound that can be included in the treatment liquid.

Examples of the antibacterial agent include sorbic acid, benzoic acid, dehydroacetic acid, phosphomycin, penicillin, sulbactam, and diaphenyl sulfone.

### (Reducing Sulfur Compound)

The treatment liquid may include a reducing sulfur compound.

The reducing sulfur compound is a compound different from the compound that can be included in the treatment liquid.

The reducing sulfur compound is a compound that has reducing properties and includes a sulfur atom.

The reducing sulfur compound can improve a corrosion preventing action of the treatment liquid. That is, the reducing sulfur compound can act as an anticorrosive agent.

Examples of the reducing sulfur compound include mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Among those, a compound having an SH group (mercapto compound) is preferable, and 1-thioglycerol, sodium 3-mercapto-1-propanesulfonate, 2-mercaptoethanol, 3-mercapto-1-propanol, or thioglycolic acid is more preferable.

The reducing sulfur compound may be used alone or in combination of two or more kinds thereof.

A content of the reducing sulfur compound is preferably 0.01% to 10% by mass, more preferably 0.05% to 5% by mass, and still more preferably 0.1% to 3% by mass with respect to the total mass of the treatment liquid.

A content of the reducing sulfur compound is preferably 0.01% to 30.0% by mass, more preferably 0.05% to 25.0% by mass, and still more preferably 0.5% to 20.0% by mass with respect to the total mass of the components in the treatment liquid excluding the solvent.

### [Properties of Treatment Liquid]

Hereinafter, the properties of the treatment liquid of the embodiment of the present invention will be described.

(pH)

From the viewpoint that the removability of the metal part is more excellent, a pH of the treatment liquid of the embodiment of the present invention is preferably 8.0 or less, more preferably 7.0 or less, and still more preferably 5.0 or less. From the viewpoint that the removability of the metal part is more excellent and the dissolution of the insulating film is further suppressed, a lower limit of the pH is preferably 0.5 or more, more preferably 3.0 or more, and still more preferably 4.0 or more.

The pH of the treatment liquid can be measured by a method in accordance with JIS Z8802-1984, using a known pH meter. The measurement temperature is set to 25° C.

### (Coarse Particles)

The treatment liquid may include coarse particles, but a content thereof is preferably low.

The coarse particles mean particles having a diameter (particle diameter) of 1 μm or more in a case where the shape of the particles is regarded as a sphere. Furthermore, the particles included in the insoluble particles may be included in the coarse particles.

As a content of the coarse particles in the treatment liquid, the content of the particles having a particle diameter of 1 μm or more is preferably 100 particles or less, and more preferably 50 particles or less per milliliter of the treatment liquid. A lower limit thereof is preferably 0 or more, and more preferably 0.01 or more per milliliter of the treatment liquid.

The coarse particles included in the treatment liquid correspond to particles of dirt, dust, organic solids, inorganic solids, and the like included as impurities in raw materials, and particles of dirt, dust, and organic solids, and inorganic solids brought in as contaminants during the preparation of the treatment liquid, in which the particles are finally present as particles without being dissolved in the treatment liquid.

The content of the coarse particles present in the treatment liquid can be measured in the liquid phase using a commercially available measuring device in a light scattering type liquid particle measuring method using a laser as a light source.

Examples of a method for removing the coarse particles include a purification treatment such as filtering which will be described later.

### <Method for Producing Treatment Liquid>

The treatment liquid can be produced by a known method. Hereinafter, a method for producing the treatment liquid will be described in detail.

### [Liquid Preparing Step]

As the method for preparing the treatment liquid, for example, the treatment liquid can produced by mixing each of the components.

The order and/or timing of mixing each of the components is not particularly limited, and examples thereof include a method in which a fluoride source, periodic acid or a salt thereof, and a surfactant are sequentially added to a container to which purified pure water has been put, and then the mixture is stirred to be mixed. In addition, a pH adjuster may be added to adjust the pH of the mixed solution, thereby preparing a liquid. In addition, in a case where water and each of the components are added to the container, the components may be added all at once or dividedly a plurality of times.

As a stirring device and a stirring method used for preparing the treatment liquid, a known device may be used as a stirrer or a disperser. Examples of the stirrer include an industrial mixer, a portable stirrer, a mechanical stirrer, and a magnetic stirrer. Examples of the disperser include an industrial disperser, a homogenizer, an ultrasonic disperser, and bead mills.

The mixing of each of the components in the liquid preparing step of the treatment liquid, a purification treatment which will be described later, and the storage of the produced treatment liquid are preferably performed at 40° C. or lower, and more preferably performed at 30° C. or lower. In addition, a lower limit thereof is preferably 5° C. or higher, and more preferably 10° C. or higher. By performing the preparation of the treatment liquid, the treatment, and/or the storage of the treatment liquid in the temperature ranges, the performance can be stably maintained for a long period of time.

### (Purification Treatment)

It is preferable that any one or more of the raw materials for producing the treatment liquid are subjected to a purification treatment in advance. Examples of the purification treatment include known methods such as distillation, ion exchange, and filtration (filtering).

With regard to the degree of purification, it is preferable to perform the purification until the purity of the raw material is 99% by mass or more, and it is more preferable to perform the purification until the purity of the stock solution is 99.9% by mass or more.

Examples of the method for the purification treatment include a method in which raw materials are passed through an ion exchange resin, a reverse osmosis membrane (RO membrane), or the like, distillation of a raw materials, and filtering which will be described later.

As the purification treatment, a plurality of the purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purification treatment may be carried out a plurality of times.

### (Filtering)

A filter that is used for the filtering is not particularly limited as long as it is a filter which has been used in filtration applications and the like since the related art. Examples thereof include filters formed of fluororesins such as polytetrafluoroethylene (PTFE) and tetrafluoroethylene perfluoroalkyl vinyl ether copolymer (PFA), polyamide-based resins such as nylon, and polyolefin resins (including those with a high density and an ultra-high molecular weight) such as polyethylene and polypropylene (PP). Among these materials, a material selected from the group consisting of the polyethylene, the polypropylene (including a high-density polypropylene), the fluororesin (including PTFE and PFA), and the polyamide-based resin (including nylon) is preferable, and the filter with the fluororesin is more preferable. In a case of performing the filtration of the raw materials using a filter formed with these materials, high-polarity foreign matters which are likely to cause defects can be effectively removed.

A critical surface tension of the filter is preferably 70 to 95 mN/m, and more preferably 75 to 85 mN/m. Furthermore, the value of the critical surface tension of the filter is a nominal value of a manufacturer. By using a filter having a critical surface tension in the ranges, high-polarity foreign matters which are likely to cause defects can be effectively removed.

A pore diameter of the filter is preferably 2 to 20 nm, and more preferably 2 to 15 nm. By setting the pore diameter of the filter to be in the ranges, it is possible to reliably remove fine foreign matters such as impurities and aggregates included in the raw materials while suppressing clogging in filtering. With regard to the pore diameters herein, reference can be made to nominal values of filter manufacturers.

The filtering may be performed only once or twice or more. In a case where the filtering is performed twice or more, the filters used may be the same as or different from each other.

Furthermore, the filtering is preferably performed at room temperature (25° C.) or lower, more preferably performed at 23° C. or lower, and still more preferably performed at 20° C. or lower. In addition, the temperature is preferably 0° C. or higher, more preferably 5° C. or higher, and still more preferably 10° C. or higher. By performing the filtering in the temperature ranges, the amount of particulate foreign matter and impurities dissolved in the raw material can be reduced, and the foreign matter and the impurities can be efficiently removed.

### (Container)

The treatment liquid (including an aspect of a diluted treatment liquid which will be described later) can be packed in any container, stored, transported, and used as long as corrosiveness or the like is not problematic.

In semiconductor applications, as the container, a container that has a high degree of cleanliness inside the container and suppressed elution of impurities from an inner wall of an accommodating portion of the container into each liquid is preferable. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited to these.

In addition, as the container for accommodating the treatment liquid, a container in which a liquid contact portion with each liquid, such as an inner wall of the accommodating portion, is formed from a fluororesin (perfluororesin) or a metal which has been subjected to rust prevention and metal elution prevention treatments is preferable.

It is preferable that the inner wall of the container is formed of one or more resins selected from the group consisting of a polyethylene resin, a polypropylene resin, and a polyethylene-polypropylene resin, or a resin different from the resins, or a metal which has been subjected to rust prevention and metal elution prevention treatments, such as stainless steel, Hastelloy, Inconel, and Monel.

The different resin is preferably the fluororesin (perfluororesin). In this manner, by using a container having an inner wall formed of a fluororesin, the occurrence of a problem of elution of ethylene or propylene oligomers can be suppressed, as compared with a container having an inner wall formed of a polyethylene resin, a polypropylene resin, or a polyethylene-polypropylene resin.

Examples of such a container having an inner wall which is a fluororesin include a FluoroPure PFA composite drum manufactured by Entegris Inc. In addition, the containers described on page 4 of JP1991-502677A (JP-H03-502677A), page 3 of WO2004/016526A, and on pages 9 and 16 of WO99/46309A can also be used.

In addition, for the inner wall of the container, quartz and an electropolished metal material (that is, a completely electropolished metal material) are also preferably used, in addition to the fluororesin.

The metal material used for producing the electropolished metal material is preferably a metal material which includes at least one selected from the group consisting of chromium and nickel, and has a total content of chromium and nickel of more than 25% by mass with respect to a total mass of the metal material, and examples thereof include stainless steel and a nickel-chromium alloy.

The total content of chromium and nickel in the metal material is more preferably 30% by mass or more with respect to a total mass of the metal material.

Furthermore, an upper limit of the total content of Cr and Ni in the metal material is generally preferably 90% by mass or less.

As a method for electropolishing the metal material, the known method can be used.

For example, the methods described in paragraphs [0011] to [0014] of JP2015-227501A, paragraphs [0036] to [0042] of JP2008-264929A, or the like can be used.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during storage, the inside of the container may be purged with an inert gas (nitrogen, argon, and the like) having a purity of 99.99995% by volume or more. Particularly, a gas with a low moisture content is preferable. In addition, during the transportation and the storage, the temperature may be normal temperature or may be controlled in a range of −20° C. to 20° C. to prevent deterioration.

### (Clean Room)

It is preferable that the handling including the production of the treatment liquid, the opening and the cleaning of the container, the filling of the cleaning composition, and the like, a treatment analysis, and a measurement are all performed in a clean room. It is preferable that the clean room satisfies 14644-1 clean room standards. The clean room preferably satisfies any of International Organization for Standardization (ISO) class 1, ISO class 2, ISO class 3, or ISO class 4, more preferably ISO class 1 or ISO class 2, and still more preferably ISO class 1.

### [Diluting Step]

The treatment liquid may be provided to be used as a treatment liquid which has been diluted (diluted treatment liquid) after a diluting step of diluting the treatment liquid using a diluent.

Furthermore, the diluted treatment liquid is also an aspect of the treatment liquid of the embodiment of the present invention as long as it satisfies the requirements of the present invention.

Examples of the diluted liquid include water and an aqueous solution including isopropanolamine (1-amino-2-propanol) or ammonia.

It is preferable that the diluted liquid used in the diluting step is subjected to a purification step in advance. In addition, it is more preferable that the diluted treatment liquid obtained in the diluting step is subjected to a purification treatment.

Examples of the purification treatment include an ion component reducing treatment using an ion exchange resin, an RO membrane, or the like, and a foreign matter removing treatment using filtering, which are described as the purification treatment for the treatment liquid, and it is preferable to perform any of these treatments.

A dilution ratio of the treatment liquid in the diluting step may be appropriately adjusted depending on the kind and the content of each component, and the use target and the purpose of the treatment liquid. A ratio (dilution ratio) of the diluted treatment liquid to the treatment liquid before the dilution in terms of a mass ratio or a volume ratio (volume ratio at 23° C.) is preferably 1.5 to 10,000 times, more preferably 2 to 2,000 times, and still more preferably 50 to 1,000 times.

In addition, a treatment liquid (diluted treatment liquid) including each component in an amount obtained by dividing a suitable content of each component (excluding water) which can be included in the treatment liquid by a dilution ratio in the range (for example, 100) can also be suitably put into practical use.

In other words, a suitable content of each component (excluding water) with respect to the total mass of the diluted treatment liquid is an amount obtained, for example, by dividing the amount described as the suitable content of each component with respect to the total mass of the treatment liquid (treatment liquid before the dilution) by a dilution ratio in the ranges (for example, 100).

A change in pH before and after the dilution (a difference between the pH of the treatment liquid before the dilution and the pH of the diluted treatment liquid) is preferably 2.0 or less, more preferably 1.8 or less, and still more preferably 1.5 or less.

It is preferable that the pH of the treatment liquid before dilution and the pH of the diluted treatment liquid are each in the suitable aspect.

A specific method for the diluting step of diluting the treatment liquid may be performed according to the liquid preparing step for the treatment liquid. The stirring device and the stirring method used in the diluting step may be performed, using the known stirring device described in the liquid preparing step of the treatment liquid.

### <Use of Treatment Liquid>

A use of the treatment liquid of the embodiment of the present invention is not particularly limited, but the treatment liquid can be suitably used in a step of removing a specific member from a semiconductor substrate. Among these, the treatment liquid of the embodiment of the present invention is preferably used as a cleaning liquid, an etchant, or a resist stripper, and more preferably used as the cleaning liquid. Examples of the cleaning liquid include a cleaning liquid after film formation, a cleaning liquid after chemical mechanical polishing (CMP), and a residue removing liquid after etching, and among these, the cleaning liquid after film formation is preferable.

As described above, in a case of using the treatment liquid, a diluted treatment liquid obtained by diluting the treatment liquid may be used.

### [Object to Be Treated]

Examples of an object to be treated, which can be suitably treated with the treatment liquid of the embodiment of the present invention, include an object to be treated, having an insulating film and a metal part on a semiconductor substrate.

Furthermore, the expression, “on the semiconductor substrate”, is used to encompass, for example, front and back surfaces, a side surface, and the inside of a groove of the semiconductor substrate. In addition, the metal part on the semiconductor substrate includes not only a case where the metal part is directly on a surface of the semiconductor substrate, but also a case where the metal part is on the semiconductor substrate through another layer.

In addition, the semiconductor substrate may simultaneously have the metal parts in a plurality of aspects as described above. That is, the semiconductor substrate may have plural kinds of metal parts.

The semiconductor substrate as the object to be treated is not particularly limited, and examples thereof include a substrate having a metal wiring film, a barrier film, and the like on a surface of a wafer constituting the semiconductor substrate.

Examples of the wafer constituting a semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), and antimony (Sb)), and a p-type silicon wafer in which a silicon wafer is doped with a trivalent atom (for example, boron (B) and gallium (Ga)). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the metal included in the metal part include at least one metal M selected from the group consisting of aluminum (Al), titanium (Ti), chromium (Cr), manganese (Mn), cobalt (Co), nickel (Ni), copper (Cu), zirconium (Zr), molybdenum (Mo), ruthenium (Ru), lanthanum (La), hafnium (Hf), tantalum (Ta), tungsten (W), osmium (Os), platinum (Pt), and iridium (Ir).

The metal part may be a substance containing a metal (metal atom), and examples thereof include a simple substance of a metal M and an alloy including the metal M.

A content of the metal atom in the metal part is preferably 80% by mass or more, and more preferably 90% by mass or more with respect to a total mass of the metal part. An upper limit thereof is 100% by mass since the metal part may be the metal itself.

The semiconductor substrate preferably has a metal part including at least one metal selected from the group consisting of Ti, Zr, Mo, Ru, Hf, Ta, and W, more preferably has a metal part including at least one metal selected from the group consisting of Mo, Ru, and W, and still more preferably has a metal part including Ru.

The metal part may be a film (residue) which is formed in an undesirable region that may occur in a case where a film as a target is formed. The film formed on the undesirable region includes an aspect in which the films are not linked to each other. Furthermore, the film formed in such an undesirable region as described above will also be referred to as a “film formation residue” hereinafter.

It is also preferable that the metal part is a metal film including a metal.

As the metal film contained in the semiconductor substrate, a metal film including the metal M is preferable, a metal film including at least one metal selected from the group consisting of Al, Ti, Co, Cu, Mo, Ru, Ta, and W is more preferable, a metal film including at least one metal selected from the group consisting of Al, Ti, Co, Cu, Ru, Ta, and W is still more preferable, a metal film including at least one metal selected from the group consisting of Ti, Co, Cu, Ru, and W is particularly preferable, and a metal film including Ru is most preferable.

Examples of the metal film including at least one metal selected from the group consisting of Ti, Co, Cu, Ru, and W include a film containing titanium as a main component (Ti-containing film), a film containing cobalt as a main component (Co-containing film), a film containing copper as a main component (Cu-containing film), a film containing ruthenium as a main component (Ru-containing film), and a film containing tungsten as a main component (W-containing film).

Examples of the titanium-containing film (metal film containing titanium as a main component) include a metal film consisting of only a metal Ti (titanium metal film) and a metal film made of an alloy consisting of a metal titanium and another metal (titanium alloy metal film).

Examples of the cobalt-containing film (metal film including cobalt as a main component) include a metal film consisting of only metal cobalt (cobalt metal film), and a metal film made of an alloy consisting of metal cobalt and another metal (cobalt alloy metal film).

Examples of the copper-containing film include a wiring line film consisting of only metal copper (copper wiring line film), and a wiring line film made of an alloy consisting of metal copper and another metal (copper alloy wiring line film).

Examples of the ruthenium-containing film include a metal film consisting of only metallic ruthenium (ruthenium metal film) and a metal film made of an alloy consisting of metallic ruthenium and another metal (ruthenium alloy metal film). The ruthenium-containing film is often used as a wiring layer and a barrier metal.

Examples of the tungsten-containing film (metal film including tungsten as a main component) include a metal film consisting of only tungsten (tungsten metal film) and a metal film made of an alloy consisting of tungsten and another metal (tungsten alloy metal film).

The tungsten-containing film is used, for example, as a barrier metal or a connection part between a via and a wiring line.

Examples of the insulating film contained in the semiconductor substrate include a silicon oxide film (for example, a silicon dioxide (SiO₂) film and a tetraethyl orthosilicate (Si(OC₂H₅)₄) film (TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film). The silicon oxide film or the low-dielectric-constant (low-k) film is preferable, and the silicon oxide film is more preferable.

The insulating film may be patterned.

Among the objects to be treated, an object to be treated, including a ruthenium metal film or a ruthenium alloy metal film, and a silicon oxide film or a low-dielectric-constant (low-k) film, is preferable. In addition, it is also preferable that the object to be treated includes the above-described film residues.

### [Method for Producing Object to Be Treated]

A method for forming the insulating film, the titanium-containing film, the cobalt-containing film, the copper-containing film, the ruthenium-containing film, the tungsten-containing film, the metal compound film, and the like on a wafer constituting a semiconductor substrate is not particularly limited as long as it is a method usually performed in this field.

Examples of the method for forming the insulating film include a method in which a wafer constituting a semiconductor substrate is subjected to a heat treatment in the presence of an oxygen gas to form a silicon oxide film, and then a gas of silane and ammonia is introduced thereto to form a silicon nitride film by a chemical vapor deposition (CVD) method.

Examples of the method for forming the titanium-containing film, the cobalt-containing film, the copper-containing film, the ruthenium-containing film, the tungsten-containing film, and the metal compound film include a method in which a circuit is formed on a wafer having the insulating film by a known method such as a resist, and then a titanium-containing film, a cobalt-containing film, a copper-containing film, a ruthenium-containing film, a tungsten-containing film, and a metal compound film are formed by a method such as plating, a sputtering method, a CVD method, a molecular beam epitaxy (MBE) method, and an atomic layer deposition (ALD) method.

In a case where a metal film is formed by the method, a metal film may be formed even in an undesirable region and a film formation residue may be generated.

In addition, the object to be treated may be obtained by subjecting the substrate manufactured by the method to a predetermined treatment. Examples of the predetermined treatment include an etching treatment, a CMP treatment, and a resist pattern forming treatment.

In a case where the etching treatment is carried out, metal residues (metal parts) that cannot be completely removed by the etching treatment can be generated.

In addition, in a case where the CMP treatment is carried out, a metal residue (metal part) derived from the metal film can be generated.

### <Method for Using Treatment Liquid>

Examples of a method for using the treatment liquid, that is, a method for treating the object to be treated include a method in which the object to be treated and the treatment liquid are brought into contact with each other. Hereinafter, the step of bringing the object to be treated and the treatment liquid into contact with each other will also be referred to as a “contact step”.

The object to be treated is as described above, and examples of the object to be treated include an object to be treated, having a metal part and an insulating film.

In a case where the object to be treated includes the insulating film and the metal part in carrying out the contact step, the dissolution of the insulating film is suppressed and at least a part of the metal part can be removed.

In a case where the treatment liquid is used as a cleaning liquid after film formation, it is preferable that the object to be treated includes the above-described film formation residues, and the film formation residues can be removed by a treatment using the treatment liquid while suppressing the dissolution of the insulating film.

In a case where the treatment liquid is used as a cleaning liquid after CMP or a residual removing liquid after etching, it is preferable that the object to be treated includes the above-described metal residue, and the metal residue (metal part) can be removed by a treatment using the treatment liquid while suppressing the dissolution of the insulating film.

In a case where the treatment liquid is used as a resist stripper, a resist pattern is preferably formed on the object to be treated, and the resist pattern can be removed while suppressing the dissolution of the insulating film.

In a case where the treatment liquid is used as an etchant, the object to be treated preferably has a metal film, and a part or the whole of the metal film can be removed while suppressing the dissolution of the insulating film.

The method in which the object to be treated and the treatment liquid are brought into contact with each other is not particularly limited, and examples thereof include a method in which the object to be treated is immersed in the treatment liquid placed in a tank, a method in which the treatment liquid is sprayed onto the object to be treated, a method in which the treatment liquid is flown onto the object to be treated, and a combination thereof. The method may be appropriately selected depending on the purpose.

In addition, the method may appropriately adopt a mode usually performed in the field. For example, scrub cleaning in which a cleaning member such as a brush is physically brought into contact with a surface of an object to be treated while supplying a treatment liquid to remove residues and the like, spinning (dropping) cleaning in which a treatment liquid is dropped while rotating an object to be treated, or the like may be used. From the viewpoint that impurities remaining on a surface of the object to be treated can be further reduced, it is preferable that the object to be treated immersed in the treatment liquid is subjected to an ultrasonic treatment.

The contact between the object to be treated and the treatment liquid in the contact step may be carried out only once or twice or more. In a case where the contact is carried out two or more times, the same method may be repeated or different methods may be combined.

A method for the contact step may be either of a single-wafer method and a batch method.

The single-wafer method is generally a method in which objects to be treated are treated one by one, and the batch method is generally a method in which a plurality of objects to be treated are treated at the same time.

The temperature of the treatment liquid is not particularly limited as long as it is a temperature usually used in this field. Generally, the cleaning is performed at room temperature (about 25° C.), but any temperature can be selected in order to improve the cleaning properties and suppress the damage resistance to a member. For example, the temperature of the treatment liquid is preferably 10° C. to 60° C., and more preferably 15° C. to 50° C.

The pH of the treatment liquid is preferably a suitable aspect of the pH of the treatment liquid described above. It is preferable that the pH of the diluted treatment liquid is also in the suitable aspect of the pH of the treatment liquid described above.

A contact time between the object to be treated and the treatment liquid can be appropriately changed depending on the type and the content of each component included in the treatment liquid, and the use target and the purpose of the treatment liquid. Practically, the contact time is preferably 10 to 120 seconds, more preferably 20 to 90 seconds, and still more preferably 30 to 60 seconds.

A supply amount (supply rate) of the treatment liquid is preferably 50 to 5,000 mL/min, and more preferably 500 to 2,000 mL/min.

In the contact step, a mechanical stirring method may be used in order to further improve the cleaning ability of the treatment liquid.

Examples of the mechanical stirring method include a method in which the treatment liquid is circulated on the object to be treated, a method in which the treatment liquid is flown or sprayed on the object to be treated, and a method in which the treatment liquid is stirred with ultrasonic waves or megasonic waves.

In addition, after the contact step, a step of cleaning the object to be treated by wiping with a solvent (hereinafter also referred to as a “rinsing step”) may be performed.

The rinsing step is continuously performed after the contact step, and is preferably a step of performing rinsing with a rinsing solvent (rinsing liquid) for 5 to 300 seconds. The rinsing step may be performed using the mechanical stirring method.

Examples of the rinsing solvent include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, and the like) may be used.

As the method in which the rinsing solvent is brought into contact with the object to be treated, the method in which the treatment liquid is brought into contact with the object to be treated can be similarly applied.

In addition, a drying step of drying the object to be treated may be performed after the rinsing step.

Examples of the drying method include a spin drying method, a method in which a dry gas is flown through an object to be treated, a method in which a substrate is heated by a heating unit such as a hot plate and an infrared lamp, a Marangoni drying method, a Rotagoni drying method, an isopropyl alcohol (IPA) drying method, and a method obtained by any combination thereof.

In addition, the contact step, that is, the method for treating an object to be treated can be suitably applied to a step of manufacturing an electronic device.

The treatment method may be carried out in combination before or after other steps performed on a substrate. The treatment method may be incorporated into other steps while carrying out the treatment method, or the treatment method may be incorporated into the other steps.

Examples of those other steps include a step of forming a structure such as a metal wire, a gate structure, a source structure, a drain structure, an insulating film, a ferromagnetic layer, and a non-magnetic layer (for example, layer formation, etching, chemical mechanical polishing, and modification), a resist forming step, an exposure step and a removing step, a heat treatment step, a cleaning step, and an inspection step.

The treatment method may be performed at any stage in a back-end-of-the-line (BEOL) process, a middle-of-the-line (MOL) process, a front-end-of the line (FEOL) process, and is preferably performed in the front-end-of the like process or the middle-of-the-line process.

### EXAMPLES

Hereinafter, the present invention will be described in more detail with reference to Examples.

The materials, the amounts of materials used, the proportions, the treatment details, the treatment procedure, and the like shown in Examples below may be modified as appropriate as long as the modifications do not depart from the spirit of the present invention. Therefore, the scope of the present invention should not be construed as being limited to Examples shown below.

### <Preparation of Treatment Liquid>

Each component shown below was mixed to prepare a treatment liquid used in each of Examples and Comparative Examples. The content of each component in the treatment liquid was set as shown in the table shown in the latter part, and the pH of each treatment liquid was adjusted to a value shown in the table, using ethyltrimethylammonium hydroxide. Furthermore, the pH of the treatment liquid used in Example 34 was adjusted using sulfuric acid.

Moreover, the remainder of each treatment liquid is water. In a case where the following component is a mixture of a solvent and the component, the content in the table indicates the content of the component excluding the solvent.

As any of the respective components used in each of Examples and each of Comparative Examples, a component classified into a semiconductor grade or a high-purity grade equivalent to the semiconductor grade was used.

Hereinafter, each of the components will be described.

### [Periodic Acid or Salt Thereof]

IO-1: Periodic acid (aqueous periodic acid solution)

### [Fluoride Source]

F-1: Hydrofluoric acid (aqueous hydrogen fluoride solution)
F-2: Hexafluorozirconic acid (aqueous H₂ZrF₆ solution)
F-3: Hexafluorotitanic acid (aqueous H₂TiF₆ solution)
F-4: Hexafluorophosphoric acid (aqueous HPF₆ solution)
F-5: Tetrafluoroboric acid (aqueous HBF₄ solution)
F-6: Ammonium fluoride (NH₄F)

### [Surfactant]

A-1:1-Dodecylpyridinium chloride (molecular weight: 283.88)
A-2: Trimethyloctylammonium chloride (molecular weight: 207.79)
A-3: Decyltrimethylammonium chloride (molecular weight: 235.89)
A-4: Hexamethonium hydroxide (molecular weight: 236.40)
A-5: Dodecyltrimethylammonium chloride (molecular weight: 263.89)
A-6: N,N-Dimethyltetradecylamine (molecular weight: 241.46)
AC-1: Hexadecyltrimethylammonium chloride (molecular weight: 320.00)
AC-2: Trimethyloctadecylammonium chloride (molecular weight: 348.05)
B-1: Lauryl phosphoric acid (“NIKKOL HLP” manufactured by Nikko Chemicals Co., Ltd.)
B-2: Tridecanoic acid (manufactured by FUJIFILM Wako Pure Chemical Corporation)
B-3: Sodium dodecyl sulfate (manufactured by FUJIFILM Wako Pure Chemical Corporation)
C-1: Polyoxyethylene lauryl ether (“EMULGEN 104P” manufactured by Kao Corporation)
C-2: Polyoxyalkylene alkyl ether (“EMULGEN LS-106” manufactured by Kao Corporation)
C-3:4-(1,1,3,3-Tetramethylbutyl)phenyl-polyethylene glycol (polyoxyethylene chain number: 6 or 7, HLB value: 12.4, “Triton™ X-114” manufactured by Sigma-Aldrich Co. LLC)
C-4:4-(1,1,3,3-Tetramethylbutyl)phenyl-polyethylene glycol (polyoxyethylene chain number: 9 or 10, HLB value: 13.5, “Triton™ X-100” manufactured by Sigma-Aldrich Co. LLC)
C-5:4-(1,1,3,3-Tetramethylbutyl)phenyl-polyethylene glycol (polyoxyethylene chain number: 40, HLB value: 17.9, “Triton™ X-405” manufactured by Sigma-Aldrich Co. LLC.)
CC-1: 1H, 1H,2H,2H-Heptadecafluoro-1-decanol (manufactured by Tokyo Chemical Industry Co., Ltd.)

Furthermore, AC-1, AC-2, and CC-1 are surfactants that do not satisfy the requirement A and the requirement C, which are used in Comparative Examples.

### <Evaluation Methods>

Hereinafter, the evaluation methods for each treatment liquid will be described.

### [Ru Film Etching Rate]

An Ru film (film consisting of single Ru) was formed on one surface of a commercially available silicon wafer (12 inches) using a sputtering method to obtain an Ru film wafer.

The obtained Ru film wafer was cut into a 2 cm square to obtain a sample, and the sample was placed in a container filled with each treatment liquid and subjected to a treatment with the treatment liquid for 1 minute. The treatment was carried out while stirring the treatment liquid. The temperature of the treatment liquid was 25° C.

A thickness of the Ru film before the treatment and a thickness of the Ru film after the treatment were measured by a fluorescent X-ray analyzer for thin film evaluation (XRF AZX-400, manufactured by Rigaku Corporation), a change in thickness of the Ru film before and after the treatment was calculated, and an etching rate (Å/min) of the Ru film was further calculated.

### [TEOS Film Etching Rate]

A TEOS film was formed on one surface of a commercially available silicon wafer (12 inches) using tetraethyl orthosilicate (TEOS) as a raw material by a plasma CVD method to obtain a TEOS film wafer.

The obtained TEOS film wafer was cut into a 2 cm square to obtain a sample, and the sample was placed in a container filled with each treatment liquid and subjected to a treatment with the treatment liquid for 5 minutes. The treatment was carried out while stirring the treatment liquid. The temperature of the treatment liquid was 25° C.

A thickness of the Ru film was measured with a spectroscopic ellipsometer (“Vase” manufactured by J. A. Woollam Japan) for the sample before the treatment and the sample after the treatment, a change in thickness of the TEOS film before and after the treatment was calculated, and an etching rate (Å/min) of the TEOS film was further calculated.

### [Metal Part Removability and Insulating Film Dissolution Suppressibility]

First, a procedure for manufacturing a sample (object to be treated) for evaluation will be described.

A liner film (1 nm) of titanium nitride and an interlayer insulating film (100 nm) of silicon oxide were formed in this order on a commercially available silicon wafer (8 inches) by a sputtering method. In the wafer on which each film was formed, a wiring groove (a width of 60 nm and a depth of 100 nm) was formed in the interlayer insulating film. After forming the wiring groove, an Ru wiring line was formed in the wiring groove such that the thickness of the Ru was 20 nm, by a sputtering method. In this case, a wiring pattern wafer, in which the Ru wiring line had been mainly formed in the wiring groove, and an Ru film (Ru film formation residue, a thickness of about 1 to 2 nm) had also been formed on the upper portion of the interlayer insulating film where the wiring groove had not been formed and a part of the wall surface part of the interlayer insulating film in the wiring groove, was obtained. That is, the wiring pattern wafer manufactured in the procedure had the insulating film and the metal part consisting of Ru (the Ru wiring and the Ru film formation residue).

The wiring pattern wafer manufactured in the procedure was used as the object to be treated, and cut into a 2 cm square to obtain a sample, and the sample was placed in a container filled with each treatment liquid and subjected to a treatment with the treatment liquid for 5 minutes. The treatment was carried out while stirring the treatment liquid. The temperature of the treatment liquid was 25° C.

After the treatment, the film was rinsed with pure water at 25° C. and dried by blowing nitrogen gas thereto to obtain a treatment sample.

For the treated sample and the sample before the treatment, cross sectional samples in the extending direction of the wiring groove and in the direction perpendicular to the extending direction were manufactured, and the cross sections were observed with a scanning electron microscope (SEM, S-4800 manufactured by Hitachi High-Tech Corporation). The observation was performed in 5 visual fields for each sample, and each evaluation in the subsequent stage was performed using an average value of values measured in each visual field.

The metal part removability was evaluated in accordance with the following standard, based on the observation results of the treatment sample and the sample before the treatment. Furthermore, the following removal rate is a value calculated by 100× (Ru film formation residue area of treatment sample)/(Ru film formation residue area of sample before treatment).

In practice, the metal part removability is preferably evaluated as AA to D.
AA: The Ru film formation residue removal rate was 90% or more and 100% or less.
A: The Ru film residual removal rate was 80% or more and less than 90%.
B: The Ru film formation residue removal rate is 60% or more and less than 80%.
C: The Ru film formation residue removal rate was 40% or more and less than 60%.
D: The Ru film formation residue removal rate was 20% or more and less than 40%.
E: The Ru film formation residue removal rate was 0% or more and less than 20%.

The insulating film dissolution suppressibility was evaluated in accordance with the following standard, based on the observation results of the treated sample and the sample before the treatment. Furthermore, the roughness increase rate is a value calculated by 100×{(arithmetic average roughness of insulating film in cross section of treated sample)−(arithmetic average roughness of insulating film in cross section of sample before treatment)}/(arithmetic average roughness of insulating film in cross section of sample before treatment).

In practice, the insulating film dissolution suppressibility is preferably evaluated as AA to D.
AA: The roughness increase rate was 0% or more and less than 10%.
A: The roughness increase rate was 10% or more and less than 20%.
B: The roughness increase rate was 40% or more and less than 60%
C: The roughness increase rate was 60% or more and less than 80%.
D: The roughness increase rate was 80% or more and less than 100%.
E: The roughness increase rate was 100% or more.

### <Results

The composition, the properties, and the evaluation results of each treatment liquid are shown in the table. Furthermore, each treatment liquid substantially did not include insoluble particles.

In the table, the pH indicates a value measured by the method.

In the table, the column of the dissolution rate represents the etching rate, and the notation of “<1” in the column of the dissolution rate indicates that the dissolution rate (etching rate) is less than 1 Å/min.

TABLE 1

| | Periodic acid or | | | | | | | | | | | |
|---|---|---|---|---|---|---|---|---|---|---|---|---|
| | salt thereof | | Fluoride source | | Surfactant | | | | | | | |
| | | Content | | Content | | Content | Surfactant/ | | Dissolution rate | | | Insulating film |
| | | [% by | | [% by | | [% by | fluoride | | [Å/min] | | Metal part | dissolution |
| | Type | mass] | Type | mass] | Type | mass] | source | pH | Ru | TEOS | removability | suppressibility |
| Example 1 | IO-1 | 1.0 | F-1 | 0.1 | A-1 | 0.001 | 0.01 | 4.5 | 56 | 10 | C | D |
| Example 2 | IO-1 | 1.0 | F-1 | 0.1 | A-1 | 0.002 | 0.02 | 4.5 | 57 | 8 | C | D |
| Example 3 | IO-1 | 1.0 | F-1 | 0.1 | A-1 | 0.01 | 0.10 | 4.5 | 58 | <1 | A | AA |
| Example 4 | IO-1 | 1.0 | F-1 | 0.1 | A-1 | 0.02 | 0.20 | 4.5 | 34 | <1 | C | AA |
| Example 5 | IO-1 | 1.0 | F-1 | 0.1 | A-1 | 0.05 | 0.50 | 4.5 | 5 | <1 | D | AA |
| Example 6 | IO-1 | 1.0 | F-1 | 0.1 | A-2 | 0.01 | 0.10 | 4.5 | 58 | 5 | C | B |
| Example 7 | IO-1 | 1.0 | F-1 | 0.1 | A-3 | 0.01 | 0.10 | 4.5 | 42 | 3 | B | A |
| Example 8 | IO-1 | 1.0 | F-1 | 0.1 | A-4 | 0.01 | 0.10 | 4.5 | 33 | 2 | B | A |
| Example 9 | IO-1 | 1.0 | F-1 | 0.1 | A-5 | 0.01 | 0.10 | 4.5 | 37 | 3 | A | A |
| Example 10 | IO-1 | 1.0 | F-1 | 0.1 | A-6 | 0.01 | 0.10 | 4.5 | 40 | 9 | B | D |
| Example 11 | IO-1 | 1.0 | F-1 | 0.1 | B-1 | 0.002 | 0.02 | 4.5 | 50 | 10 | C | D |
| Example 12 | IO-1 | 1.0 | F-1 | 0.1 | B-1 | 0.01 | 0.10 | 4.5 | 48 | 6 | B | B |
| Example 13 | IO-1 | 1.0 | F-1 | 0.1 | B-1 | 0.049 | 0.49 | 4.5 | 43 | 4 | A | B |
| Example 14 | IO-1 | 1.0 | F-1 | 0.1 | B-2 | 0.002 | 0.02 | 4.5 | 55 | 11 | D | D |
| Example 15 | IO-1 | 1.0 | F-1 | 0.1 | B-2 | 0.01 | 0.10 | 4.5 | 50 | 10 | C | C |
| Example 16 | IO-1 | 1.0 | F-1 | 0.1 | B-2 | 0.049 | 0.49 | 4.5 | 43 | 6 | B | B |
| Example 17 | IO-1 | 1.0 | F-1 | 0.1 | B-3 | 0.002 | 0.02 | 4.5 | 48 | 9 | B | D |
| Example 18 | IO-1 | 1.0 | F-1 | 0.1 | B-3 | 0.01 | 0.10 | 4.5 | 43 | 3 | A | A |
| Example 19 | IO-1 | 1.0 | F-1 | 0.1 | B-3 | 0.049 | 0.49 | 4.5 | 42 | 1 | A | A |
| Example 20 | IO-1 | 1.0 | F-1 | 0.1 | C-1 | 0.01 | 0.10 | 4.5 | 55 | 2 | B | A |
| Example 21 | IO-1 | 1.0 | F-1 | 0.1 | C-2 | 0.01 | 0.10 | 4.5 | 42 | 2 | C | A |
| Example 22 | IO-1 | 1.0 | F-1 | 0.1 | C-3 | 0.01 | 0.10 | 4.5 | 40 | 2 | C | A |
| Example 23 | IO-1 | 1.0 | F-1 | 0.1 | C-4 | 0.01 | 0.10 | 4.5 | 41 | 2 | B | A |
| Example 24 | IO-1 | 1.0 | F-1 | 0.1 | C-5 | 0.002 | 0.02 | 4.5 | 54 | 10 | C | D |
| Example 25 | IO-1 | 1.0 | F-1 | 0.1 | C-5 | 0.005 | 0.05 | 4.5 | 53 | 6 | C | B |
| Example 26 | IO-1 | 1.0 | F-1 | 0.1 | C-5 | 0.01 | 0.10 | 4.5 | 44 | 2 | AA | A |
| Example 27 | IO-1 | 1.0 | F-1 | 0.1 | C-5 | 0.02 | 0.20 | 4.5 | 30 | 1 | B | AA |
| Example 28 | IO-1 | 1.0 | F-1 | 0.1 | C-5 | 0.05 | 0.50 | 4.5 | 23 | <1 | C | AA |
| Example 29 | IO-1 | 1.0 | F-2 | 0.1 | C-5 | 0.01 | 0.10 | 4.5 | 41 | <1 | B | AA |
| Example 30 | IO-1 | 1.0 | F-3 | 0.1 | C-5 | 0.01 | 0.10 | 4.5 | 46 | <1 | B | AA |
| Example 31 | IO-1 | 1.0 | F-4 | 0.1 | C-5 | 0.01 | 0.10 | 4.5 | 48 | <1 | B | AA |
| Example 32 | IO-1 | 1.0 | F-5 | 0.1 | C-5 | 0.01 | 0.10 | 4.5 | 33 | <1 | B | AA |
| Example 33 | IO-1 | 1.0 | F-6 | 0.1 | C-5 | 0.01 | 0.10 | 4.5 | 41 | <1 | B | AA |
| Example 34 | IO-1 | 1.0 | F-1 | 0.1 | C-5 | 0.01 | 0.10 | 1.0 | 24 | 17 | C | D |
| Example 35 | IO-1 | 1.0 | F-1 | 0.1 | C-5 | 0.01 | 0.10 | 3.0 | 33 | 6 | B | C |
| Example 36 | IO-1 | 1.0 | F-1 | 0.1 | C-5 | 0.01 | 0.10 | 6.5 | 36 | <1 | B | AA |
| Comparative Example 1 | — | — | F-1 | 0.1 | C-5 | 0.01 | 0.10 | 4.5 | 0 | 19 | E | D |
| Comparative Example 2 | IO-1 | 1.0 | — | — | C-5 | 0.01 | — | 4.5 | 30 | 0 | E | AA |
| Comparative Example 3 | IO-1 | 1.0 | F-1 | 0.1 | — | — | — | 7.0 | 46 | 43 | C | E |
| Comparative Example 4 | IO-1 | 1.0 | F-1 | 0.1 | AC-1 | 0.01 | 0.10 | 4.5 | 3 | 7 | E | C |
| Comparative Example 5 | IO-1 | 1.0 | F-1 | 0.1 | AC-2 | 0.01 | 0.10 | 4.5 | 1 | 8 | E | C |
| Comparative Example 6 | IO-1 | 1.0 | F-1 | 0.1 | B-1 | 0.0009 | 0.009 | 4.5 | 52 | 35 | C | E |
| Comparative Example 7 | IO-1 | 1.0 | F-1 | 0.1 | B-1 | 0.051 | 0.51 | 4.5 | <1 | <1 | E | AA |
| Comparative Example 8 | IO-1 | 1.0 | F-1 | 0.1 | B-2 | 0.0009 | 0.009 | 4.5 | 47 | 40 | C | E |
| Comparative Example 9 | IO-1 | 1.0 | F-1 | 0.1 | B-2 | 0.051 | 0.51 | 4.5 | <1 | <1 | E | AA |
| Comparative Example 10 | IO-1 | 1.0 | F-1 | 0.1 | B-3 | 0.0009 | 0.009 | 4.5 | 43 | 25 | C | E |
| Comparative Example 11 | IO-1 | 1.0 | F-1 | 0.1 | B-3 | 0.051 | 0.51 | 4.5 | <1 | <1 | E | AA |
| Comparative Example 12 | IO-1 | 1.0 | F-1 | 0.1 | CC-1 | 0.01 | 0.10 | 4.5 | <1 | <1 | E | AA |

In addition, in Examples 3, 12, 16, 18, and 26, a treatment liquid was prepared by changing ethyltrimethylammonium hydroxide used as the pH adjuster to the following pH adjuster, and subjected to the same evaluations, and the same evaluation results as those of each of Examples could be obtained. The pH adjusters used in the preparation of the treatment liquid are ammonia, tetramethylammonium hydroxide, tetraethylammonium hydroxide, tetrapropylammonium hydroxide, tetrabutylammonium hydroxide, ethyltrimethylammonium chloride, triethylmethylammonium hydroxide, and diethyldimethylammonium hydroxide.

In addition, in Examples 33 to 36, a treatment liquid was prepared by changing ethyltrimethylammonium hydroxide used as the pH adjuster to the following pH adjuster, and subjected to the same evaluations, and the same evaluation results as those of each of Examples were obtained. The pH adjusters used in the preparation of the treatment liquid are ammonia, tetramethylammonium hydroxide, tetraethylammonium hydroxide, tetrapropylammonium hydroxide, tetrabutylammonium hydroxide, ethyltrimethylammonium chloride, triethylmethylammonium hydroxide, and diethyldimethylammonium hydroxide.

From the results in Table 1, it was confirmed that the treatment liquids of Examples which include water, a fluoride source, periodic acid or a salt thereof, and a surfactant, and satisfy at least one of the above-described requirement A, requirement B, or requirement C have excellent removability of a metal part and suppressed dissolution of the insulating film.

On the other hand, in Comparative Examples 1 to 3 which do not include any of water, a fluoride source, and periodic acid or a salt thereof, Comparative Examples 4 and 5 which do not satisfy the requirement A, Comparative Examples 6 to 11 which do not satisfy the requirement B, and Comparative Example 12 which does not satisfy the requirement C, the removability of the metal part and suppressed dissolution of the insulating film could not be achieved at the same time.

From the results in Table 1, the treatment liquid of the embodiment of the present invention had excellent removability of the metal part and suppressed dissolution of an insulating film, and can thus be used as a cleaning liquid (a cleaning liquid after CMP and a residue removing solution after etching) and an etchant. In addition, the treatment liquid can be used as a resist stripper.

From the comparison between Examples 6 and 10, and Examples 3 and 7 to 9, it was confirmed that in a case where the structure of the cationic surfactant is represented by Formula (A1) or Formula (A2), and the monovalent aliphatic hydrocarbon group having 6 or more carbon atoms has 10 or more carbon atoms, or the structure of the cationic surfactant is represented by Formula (A5), the removability of the metal part is more excellent or the dissolution of the insulating film is further suppressed.

From the comparison between Examples 14 to 16, and Examples 11 to 13 and 17 to 19, it was confirmed that in a case where the anionic surfactant has a phosphoric acid group or a salt thereof, or a sulfo group or a salt thereof (more preferably the sulfo group or a salt thereof), the removability of the metal part is more excellent or the dissolution of the insulating film is further suppressed.

From the comparison between Example 22 and Examples 23 and 26, it was confirmed that in a case where the HLB value of the nonionic surfactant is 13.0 or more (more preferably 17.5 or more), the removability of the metal part is more excellent.

From the comparison between Examples 1 and 2, and Examples 3 to 5, it was confirmed that in a case where the mass ratio of the content of the cationic surfactant to the content of the fluoride source is 0.1 to 0.5 (more preferably 0.1 to 0.2), the removability of the metal part is more excellent or the dissolution of the insulating film is further suppressed.

From the comparison between Example 24 and Examples 25 to 28, it was confirmed that in a case where the mass ratio of the content of the nonionic surfactant to the content of the fluoride source is 0.05 to 0.5 (more preferably 0.1 to 0.2), the removability of the metal part was more excellent or the dissolution of the insulating film is further suppressed.

What is claimed is:

1. A treatment liquid for a semiconductor substrate, the treatment liquid comprising:
water;
a fluoride source;
periodic acid or a salt thereof; and
a surfactant,
wherein the treatment liquid satisfies at least one of the following requirement A, requirement B, or requirement C,
requirement A: the surfactant includes a cationic surfactant, and the cationic surfactant has a monovalent aliphatic hydrocarbon group having 6 or more carbon atoms or a divalent aliphatic hydrocarbon group having 6 or more carbon atoms, and has a molecular weight of 300 or less,
requirement B: the surfactant includes an anionic surfactant, and the anionic surfactant has one or more groups selected from the group consisting of a phosphoric acid group, a carboxy group, a sulfo group, and salts thereof, and has a mass ratio of a content of the anionic surfactant to a content of the fluoride source of 0.01 to 0.5, and
requirement C: the surfactant includes a nonionic surfactant, and the nonionic surfactant has no fluorine atom, and is represented by Formula (C1), Formula (C2), or Formula (C3),
R^{C1}—(O—CH₂—CH₂)_{nC1}—OH Formula (C1)
R^{C2}—(O—C₃H₆)_{nC2}—OH Formula (C2)
R^{C3}—(O—C₃H₆)_{mC3}—(O—CH₂—CH₂)_{nC3}—OH Formula (C3)
in Formula (C1), R^{C1} represents a hydrocarbon group which does not include a fluorine atom and may have a substituent, and
nC1 represents an integer of 1 or more,
in Formula (C2), R^{C2} represents a hydrocarbon group which does not include a fluorine atom and may have a substituent, and
nC2 represents an integer of 1 or more, and
in Formula (C3), R^{C3} represents a hydrocarbon group which does not include a fluorine atom and may have a substituent, and
nC3 and mC3 each represent an integer of 1 or more.

2. The treatment liquid for a semiconductor substrate according to claim 1,
wherein the treatment liquid satisfies the requirement A.

3. The treatment liquid for a semiconductor substrate according to claim 1,
wherein the treatment liquid satisfies the requirement B.

4. The treatment liquid for a semiconductor substrate according to claim 1,
wherein the treatment liquid satisfies the requirement C.

5. The treatment liquid for a semiconductor substrate according to claim 1,
wherein the treatment liquid substantially does not include insoluble particles.

6. The treatment liquid for a semiconductor substrate according to claim 2,
wherein the treatment liquid substantially does not include insoluble particles.

7. The treatment liquid for a semiconductor substrate according to claim 3,
wherein the treatment liquid substantially does not include insoluble particles.

8. The treatment liquid for a semiconductor substrate according to claim 4,
wherein the treatment liquid substantially does not include insoluble particles.

9. The treatment liquid for a semiconductor substrate according to claim 1,
wherein the treatment liquid does not include a silicon-containing compound.

10. The treatment liquid for a semiconductor substrate according to claim 2,
wherein the treatment liquid does not include a silicon-containing compound.

11. The treatment liquid for a semiconductor substrate according to claim 3,
wherein the treatment liquid does not include a silicon-containing compound.

12. The treatment liquid for a semiconductor substrate according to claim 4,
wherein the treatment liquid does not include a silicon-containing compound.

13. The treatment liquid for a semiconductor substrate according to claim 1,
wherein a content of the surfactant is 0.0001% to 0.5% by mass with respect to a total mass of the treatment liquid.

14. The treatment liquid for a semiconductor substrate according to claim 1, further comprising:
one or more kinds of pH adjusters selected from the group consisting of ammonia, a tetramethylammonium salt, a tetraethylammonium salt, a tetrapropylammonium salt, a tetrabutylammonium salt, an ethyltrimethylammonium salt, a triethylmethylammonium salt, and a diethyldimethylammonium salt.

15. The treatment liquid for a semiconductor substrate according to claim 1, further comprising:
a corrosion inhibitor.

16. The treatment liquid for a semiconductor substrate according to claim 1,
wherein the treatment liquid is used as a cleaning liquid, an etchant, or a resist stripper.

17. A method for treating an object to be treated, comprising:
a step of bringing an object to be treated, having a metal part and an insulating film, and the treatment liquid according to claim 1 into contact with each other.

18. A method for manufacturing an electronic device, comprising:
the method for treating an object to be treated according to claim 11.
